(19) United States
(12) Patent Application Publication
(10) Pub. No.: US 2026/0341643 A1
(43) Pub. Date: Oct. 29, 2026

(54) POWER GENERATORS AND METHODS OF USING THE SAME

(71) Applicant: AES Global Holdings Pte. Ltd., Singapore (SG)

(72) Inventors: Anthony Lee Lecher, Goodyear, AZ (US); Philip Charles Schmitt, Fort Collins, CO (US); Suryan Emani, San Jose, CA (US)

(73) Assignee: AES Global Holdings Pte. Ltd., Singapore (SG)

(21) Appl. No.: 19/654,436

(22) Filed: Apr. 21, 2026

Related U.S. Application Data
(63) Continuation-in-part of application No. 19/235,409, filed on Jun. 11, 2025.
Application No. 19/235,409 is a continuation-in-part of application No. 19/007,341, filed on Dec. 31, 2024.

(51) Int. Cl. H01J 37/32

(52) U.S. Cl. CPC H01J 37/32183

(57) ABSTRACT

A system may include an exciter to provide a signal comprising a frequency. A system may include an amplifier to amplify the signal to provide an amplified signal. A system may include a match network to adjust an impedance of the system to at least one non-fifty-ohm match state. A system may include a controller to adjust the frequency.

### CROSS-REFERENCE TO RELATED APPLICATIONS

This application is a continuation-in-part of U.S. application 19/235,409 filed on Jun. 11, 2025, for POWER GENERATORS AND METHODS OF USING THE SAME, which is a continuation-in-part of U.S. application 19/007,341 filed on Dec. 31, 2024, for POWER GENERATORS AND METHODS OF USING THE SAME, which is hereby incorporated for all that is disclosed therein.

### FIELD OF THE DISCLOSURE

The present disclosure relates generally to power supplies. In particular, but not by way of limitation, the present disclosure relates to power supplies, such as radio frequency generators used in plasma processing applications.

### BACKGROUND

Radio frequency (RF) generators may be used to produce a plasma in connection with plasma processing systems. Plasma processing systems may be used to perform etching and/or deposition.

Prior techniques for plasma processing are expensive, inefficient, and inadequate. Further limitations and disadvantages will become apparent to one of skill in the art through comparison of prior techniques with the present disclosure.

### SUMMARY OF THE DISCLOSURE

The following presents a simplified summary relating to one or more aspects and/or examples disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the mechanisms disclosed herein in a simplified form to precede the detailed description presented below.

In some aspects, the techniques described herein relate to a system comprising: an oscillator configured to provide a first signal comprising a frequency and a second signal comprising the frequency and phase shifted relative to the first signal; a first amplifier configured to amplify the first signal to provide a first amplified signal to a first coil of a processing chamber; and a second amplifier configured to amplify the second signal to provide a second amplified signal to a second coil of the processing chamber.

In some aspects, the techniques described herein relate to a system, further comprising: a first match network configured to match an impedance out of the first amplifier to the first coil; and a second match network configured to match an impedance out of the second amplifier to the second coil.

In some aspects, the techniques described herein relate to a system, wherein at least one of the first match network and the second match network is configured to match to two or more non-fifty-ohm match states.

In some aspects, the techniques described herein relate to a system, wherein the oscillator, the first amplifier, the second amplifier, the first match network, the second match network, and a controller are housed within a same chassis configured to be coupled to a processing chamber housing the first coil and the second coil.

In some aspects, the techniques described herein relate to a system, further comprising DC protection circuitry configured to receive DC power from a DC power supply that is remote from the chassis, wherein the DC power is configured to provide power to at least the oscillator.

In some aspects, the techniques described herein relate to a system, further comprising a DC power supply located within the same chassis and configured to provide power to at least one of the first amplifier and the second amplifier.

In some aspects, the techniques described herein relate to a system, further comprising a DC power supply configured to remotely power at least one of the first amplifier and the second amplifier via a DC bus.

In some aspects, the techniques described herein relate to a system, further comprising: metrology configured to sense current provided by the system to at least one of the first coil and the second coil; and a controller configured to adjust current provided to at least one of the first coil and the second coil in response to the sensed current.

In some aspects, the techniques described herein relate to a system, further comprising: metrology configured to sense voltage provided by the system to at least one of the first coil and the second coil; and a controller configured to adjust voltage provided to at least one of the first coil and the second coil in response to the sensed voltage.

In some aspects, the techniques described herein relate to a system comprising: an oscillator configured to provide a radio frequency (RF) signal; a phase shifter configured to phase shift the RF signal to provide a phased shifted RF signal; at least one first amplifier configured to amplify the RF signal to generate a first amplified RF signal; and at least one second amplifier configured to amplify the phase shifted RF signal to generate a second amplified RF signal.

In some aspects, the techniques described herein relate to a system, further comprising a match network configured to match the at least one first amplifier to at least one non-fifty-ohm match state.

In some aspects, the techniques described herein relate to a system, wherein the match network is configured to match to two or more non-fifty-ohm match states.

In some aspects, the techniques described herein relate to a system, further comprising a controller, wherein the controller is configured to control the oscillator to adjust the frequency of the first amplified RF signal to match an impedance of a coil coupled to the first amplifier.

In some aspects, the techniques described herein relate to a system, wherein: the oscillator is configured to provide the RF signal to the at least one first amplifier and the at least one second amplifier; and the phase shifter is located in the at least one first amplifier or the at least one second amplifier.

In some aspects, the techniques described herein relate to a system, wherein: the at least one first amplifier comprises two or more amplifiers; and outputs of the two or more amplifiers are coupled by way of a combiner.

In some aspects, the techniques described herein relate to a system, wherein the phase shifter is configured to shift the phase of the first RF signal 90° relative to the first RF signal.

In some aspects, the techniques described herein relate to a method comprising: generating a first radio frequency (RF) signal; generating a second RF signal, wherein the second RF signal is phase shifted relative to the first RF signal; amplifying the first RF signal using at least one first amplifier to generate a first amplified RF signal; amplifying the second RF signal using at least one second amplifier to generate a second amplified RF signal; powering a first coil of a processing chamber with the first amplified RF signal; and powering a second coil of the processing chamber with the second amplified RF signal.

In some aspects, the techniques described herein relate to a method, wherein generating a second RF signal comprises generating a second RF signal that is phase shifted 90° relative to the first RF signal.

In some aspects, the techniques described herein relate to a method, further comprising matching at least one an output of the first amplifier to the first coil and an output of the second amplifier to the second coil.

In some aspects, the techniques described herein relate to a method, further comprising matching a frequency of at least the first RF signal or the second RF signal to an impedance at least one of the first coil or the second coil.

### BRIEF DESCRIPTION OF THE DRAWINGS

Various objects and advantages and a more complete understanding of the present disclosure are apparent and more readily appreciated by referring to the following detailed description and to the appended claims when taken in conjunction with the accompanying drawings:

FIG. 1 illustrates a system-level view of a system for providing a waveform to a processing chamber.

FIG. 2 is a block diagram providing additional details of DC power distribution and control.

FIG. 3 is a block diagram illustrating additional details of frequency control and match control.

FIG. 4 is a block diagram depicting examples of subcomponents of a generator.

FIG. 5 illustrates a block diagram of a single generator configured to provide power to a processing chamber.

FIG. 6 illustrates a block diagram of a generator similar to the generator of FIG. 5 with more than two power amplifiers.

FIG. 7 illustrates a block diagram of a generator similar to the generator of FIG. 6 wherein phase shifted signals are generated within power amplifiers.

FIG. 8 is a block diagram depicting examples of components that may be used in a controller.

FIG. 9 is a flowchart showing a method of powering a processing chamber.

FIG. 10 is a block diagram depicting an example generator.

FIG. 11 is a block diagram depicting another example generator.

FIG. 12 is a block diagram depicting an example system.

### DETAILED DESCRIPTION

Preliminary note: the flowcharts and block diagrams in the following figures illustrate the architecture, functionality, and operation of possible implementations of systems, methods and computer program products according to various embodiments of the present disclosure. In this regard, some blocks in these flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustrations, and combinations of blocks in the block diagrams and/or flowchart illustrations, can be implemented by special purpose hardware-based systems that perform the specified functions or acts, or combinations of special purpose hardware and computer instructions.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present disclosure.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” “comprising,” “includes,” and/or “including” are “open ended” terms and when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items, and may be abbreviated as “/”.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and/or the present specification and will not be interpreted in an idealized or overly formal sense unless expressly so defined herein. Unless otherwise limited, “coupled” means directly and indirectly coupled.

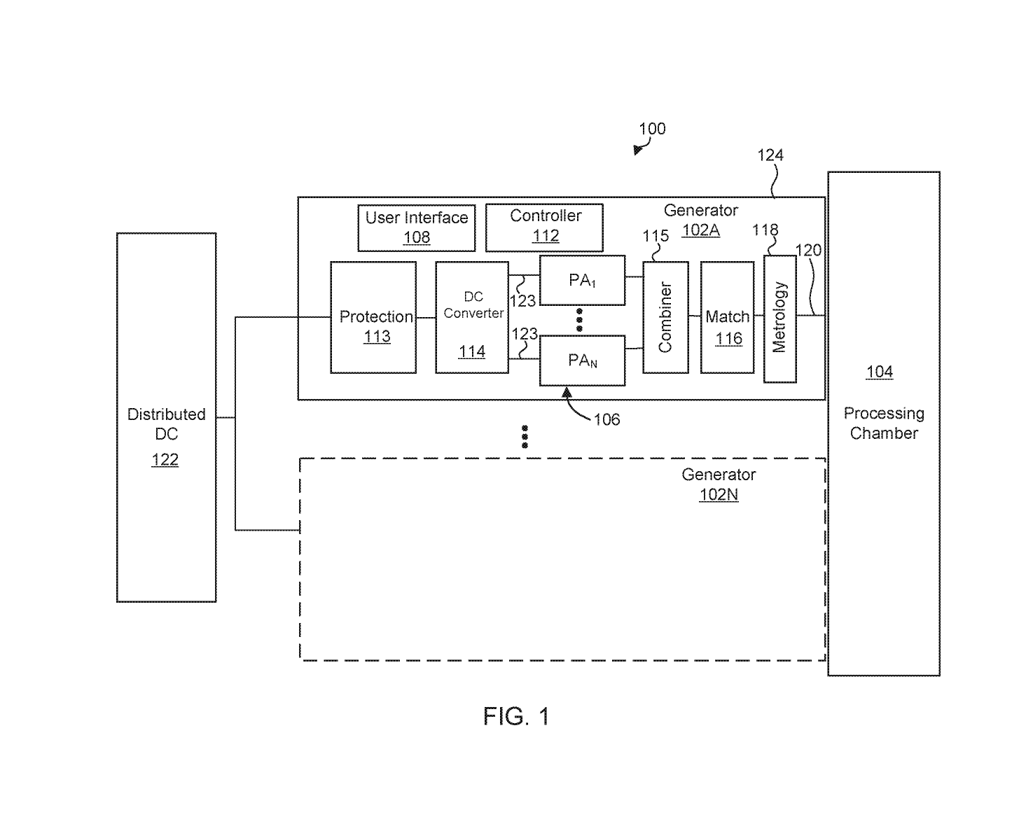

Examples disclosed herein provide functions and benefits previously unavailable by way of structural and/or operational aspects. Many of these aspects may be explained with reference to FIG. 1, which illustrates a system-level view of a system 100 that may comprise a generator 102A for providing, e.g., responsive to a user-defined output, a waveform to processing chamber 104, which may present a nonlinear plasma load to generator 102A. Generator 102A can include a user interface 108, a controller 112, protection 113, at least one power amplifier (PA) 106, a combiner 115, a match network 116, and metrology 118. In some instances, the system 100 may include a single generator 102. In other instances, the system 100 may include two or more generators, where each of the generators 102A-102N may be substantially configured (e.g., may include the same or similar hardware and/or software) as depicted for generator 102A. The system 100 may include distributed direct current (DC) 122 that provides DC power to the N generators, where N is one or more. In some examples, combiner 115 may not be necessary (for example, combiner 115 may not be necessary in the example wherein generator 102A includes a single power amplifier). The combiner 115 may be a radio frequency (RF) combiner to combine one or more RF signals and may be constructed with any of a variety of topologies such as, without limitation, a hybrid combiner.

Before detailing several design and operational aspects, it is helpful to understand the general operation of the depicted system 100. In operation, the distributed DC 122 may convert alternating current (AC) power (e.g., from AC mains of the premises where the system is deployed) to direct current (DC) power that may be provided to each of the generators 102. In some examples, the DC power may be transferred to DC converter 114 via protection 113. In some examples, protection 113 may be configured to couple DC power from the distributed DC 122 to the generator 102 in normal operation and decouple the generator 102 from the distributed DC 122 after a fault condition is detected. The DC converter 114 may be realized by a variety of alternative power conversion topologies, such as, for example, any of a variety of DC-to-DC converter topologies. For example, the DC converter 114 may comprise a linear regulator, a buck converter, a boost converter, a buck-boost converter, and/or other types of regulators and converters. DC converter 114 may provide and distribute DC power 123 to circuits of the generator 102. In some examples, DC converter 114 may couple to a supply rail of the power amplifier(s), PA_{N},to drive the rail voltage of each amplifier, PA_{N}. In some examples, a combiner 115 may be coupled to the output terminals of amplifiers, PA_{N}, to combine the amplified signals that are output by the power amplifiers, PA_{N}.

In some examples, the generator 102 may comprise N power amplifiers, PA_{N}, where N is one or more. In some examples, power amplifiers PA_{N} may be push-pull class E amplifiers. In examples including two or more power amplifiers, PA_{N,} the amplified signals from the power amplifiers, PA_{N,} may be combined using, for example, combiner 115 to provide an amplified signal at an output terminal of combiner 115. In some examples, the amplified signal may be provided from combiner 115 to an input terminal of match network 116. In some examples, match network 116 may be configured to center the source characteristic impedance of the generator 102 to the characteristic impedance of the processing chamber 104. As discussed further herein, match network 116 may provide one or more characteristic impedance states to match the source impedance of the generator 102 to the processing chamber 104. In some examples, the processing chamber 104 may present a variable impedance that deviates from a fifty-ohm impedance. In some examples, match network 116 may be tuned to a match state, of a set of one or more match states, in order to improve matching of impedance between the generator 102 and the non-fifty-ohm impedance of processing chamber 104. Accordingly, the match network 116 may improve (e.g., increase) the amount of power coupled or delivered to the processing chamber 104 from the generator 102.

As discussed further herein, generator 102 may be mechanically coupled directly or directly connected to the processing chamber 104. More specifically, in contrast to systems that couple a generator to a plasma processing chamber via a fifty-ohm cable, a match network, and another fifty-ohm cable, generator 102 may be directly coupled or directly connected to the processing chamber 104 (such as depicted in FIG. 1) to avoid the cable-match-cable coupling of systems using fifty-ohm cables. Although the mechanical coupling may vary depending upon a design of the processing chamber 104, in some examples, each generator may be bolted on to the processing chamber 104. The electrical coupling between each generator 102 and the processing chamber 104 may also vary depending upon a design of electrical input(s) to the processing chamber 104, and in some examples, the output terminal 120 of each generator 102 may electrically couple to the processing chamber 104 via a pin-and-socket connection and may avoid use of a cable (e.g., a fifty-ohm cable). In some examples, terminal 120 may be referred to as a node or port. In some examples, system 100 may improve coupling between the generator 102 and the processing chamber 104 and may eliminate components in the system 100 (e.g., may eliminate cabling and additional match networks).

Several aspects are disclosed in the present disclosure, and these aspects may be combined in various combinations. Some aspects disclosed herein comprise distributed DC 122 that provides a DC bus to one or more of the generators 102. As discussed further herein, the distributed DC 122 may be remotely located from the generator(s) 102 (such as depicted in FIG. 1) so that a bulky power supply is not physically mounted to the processing chamber 104 with the generator(s) 102. Another aspect disclosed herein is utilization of frequency tuning in a single non-fifty-ohm chassis (e.g., within a single housing or enclosure 124, wherein the housing may comprise metallic components) that may be directly coupled to the processing chamber 104. Yet another aspect is frequency tuning utilized with one or more non-fifty-ohm match states provided by the match network 116. In some examples, regulation may be based on power. In other examples, in contrast to regulating power, regulating current and/or voltage may be implemented at an output of the generator(s) 102. It should be recognized that these aspects are not mutually exclusive and that none of the examples provided further herein with reference to FIGS. 1-7 should be assumed to be mutually exclusive. In other words, the aspects described with reference to FIGS. 1-7 may be combined to produce variations of the system 100, generator 102, and distributed DC 122. It is also contemplated that two or more of the generators may be housed in a common housing.

In some examples, the controller 112 may be configured to simultaneously control gain, frequency, and aspects of the match network 116 of one or more generators 102 in connection with one or more input parameter values such as, without limitation, power, voltage, and/or current. As used herein, “configured to” describes a specific adaptation to hardware and/or software. Controller112 may be configured to enable the controller 112 to operate as described herein. In some examples, metrology 118 may be configured to allow a single measurement point to enable control of frequency, power, current, and/or voltage delivered to the processing chamber 104. This approach provides an improvement to enable distinguishing between different frequencies and near frequency (in band) separation utilizing feedforward and/or feedback between controller 112 and metrology 118.

In some examples, metrology 118 may comprise one or more sensors such current transducers, voltage sensors, voltage current (VI) sensors, and/or directional couplers. Metrology 118 may also include hardware to sample and digitize analog signals provided by the sensors. Although not shown in FIG. 1, metrology 118 may be coupled to controller 112 to provide signals to the controller 112 that are indicative of, for example and without limitation, power, current, voltage, current-voltage phase, complex forward power, and/or complex reflected power.

In some examples, single enclosure 124 may comprise a line filter (not shown), an AC/DC converter (not shown) including an input coupled to the output of the line filter, a converter 114 (e.g., a fast buck converter) including an input coupled to an output of AC/DC converter, an amplifier PA (e.g., push-pull Class E amplifier) including an input coupled to an output of the converter 114, a combiner 115 including an input coupled to the output of the amplifier PA, a match 116 (e.g., a configurable fixed match) having an input coupled to the output of combiner 115, and metrology 118 (e.g., a VI sensor) including an input coupled to an output of the match 116. In some examples, metrology 118 may be referred to as a measurement component. In some examples, an RF signal may be provided at output 120. In some examples, a sinewave may be provided at output 120.

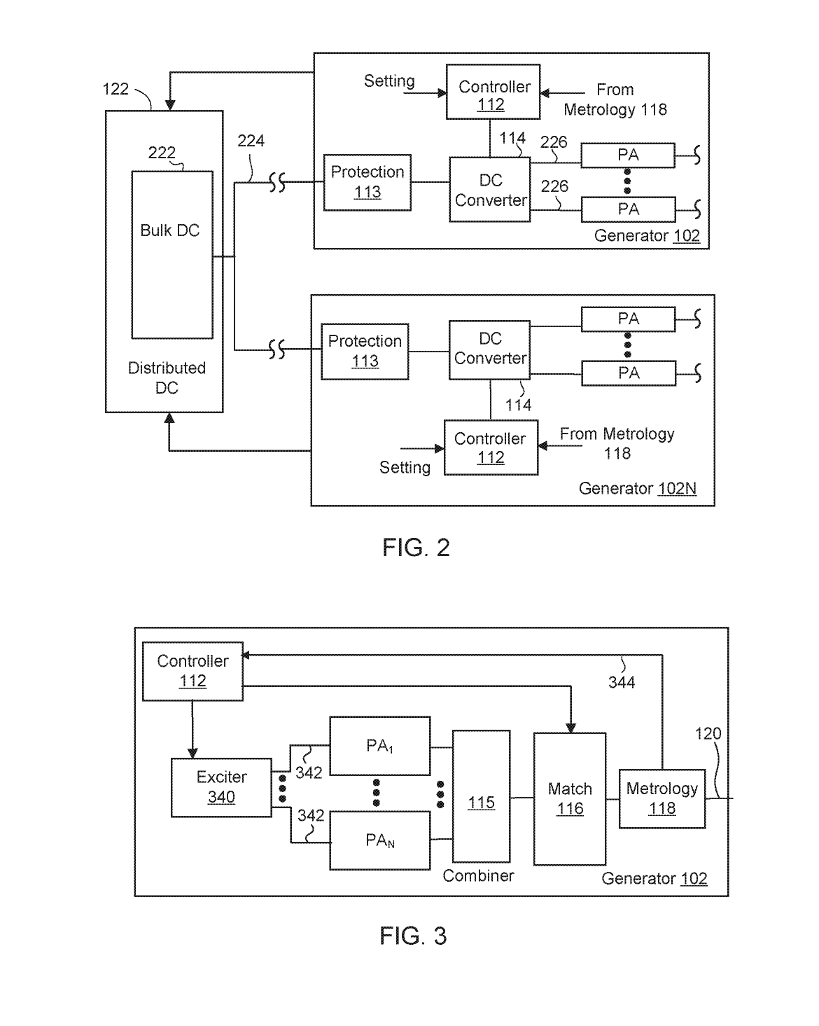

Referring next to FIG. 2, shown is a block diagram depicting aspects of DC power distribution and control of the system 100 depicted in FIG. 1. As shown, distributed DC 122 comprises bulk DC 222 that sets up a DC bus 224 that feeds DC power to each of N generators where N is one or more. The distributed DC 122 may include one or more types of DC-DC converters, such as buck, boost, buck-boost, and/or other types of converters. In addition, distributed DC 122 may include power supply components, such as, for example, various switching components, magnetic components (e.g., transformers, inductors, etc.), protection circuitry (e.g., various current protections, voltage protections, electronic fuse, etc.), measurement circuitry, control circuitry (e.g., one or more processing elements), etc. Distributed DC 122 may comprise a single output (as depicted) or multiple outputs. In examples wherein distributed DC 122 comprises multiple outputs, bus 224 may comprise a separate connection (e.g., power supply cable) between the distributed DC 122 and each generator 102A-102N. Distributed DC 122 may include internal thermal monitoring and protection.

In some examples, the protection circuitry of the distributed DC 122 may operate independently of protection 113 provided in each of the generators 102A-102N or may work in conjunction with protection 113 to provide protection (e.g., voltage, current, thermal, etc.). Distributed DC 122 may be configured to receive one or more input signals from one or more of the generators 102A-102N. The distributed DC 122 may use the received input signals to regulate output voltage, current, power, and/or other aspects of the output of distributed DC 122. For example, the distributed DC 122 may receive signals provided by controller 112, protection 113, and/or other component of a generator 102A-102N, and may use the received signals as described.

Referring next to FIG. 3, shown is a block diagram depicting an aspect of frequency tuning that may be utilized by generator 102. In some examples, generator 102 may be configured to have a non-fifty-ohm source impedance. As shown, controller 112 may be coupled to a driver exciter 340 to control, responsive to feedback 344 from metrology 118, the frequency of radio frequency signals 342 that are provided to the power amplifiers, PA_{N}. The exciter 340 may comprise an oscillator and/or a signal generator, for example, and may be referred to as an oscillator. Although not shown in FIG. 3, in some examples the phase of radio frequency signals 342 may be offset from one another (e.g., by forty-five degrees or ninety degrees). The feedback 344 from metrology 118 may include one or more power-related signals including, without limitation, voltage signals indicative of voltage at output 120, current signals indicative of current provided at output 120, and/or signals indicative of phase between the voltage and the current at output 120. In some examples, the feedback 344 from metrology 118 may comprise feedback indicative of forward and reflected power that is provided by a directional coupler (not shown). In other examples, metrology 118 may provide signals indicative of the frequency of the power at the output 120.

In some variations, the match network 116 may be configured to provide one or more non-fifty-ohm match states. As one or ordinary skill in the art (in view of this disclosure) will appreciate, the match states may be, for example, achieved by solid state match elements. For example, discrete switching of PIN diodes may be used to switch reactive elements (e.g., capacitors) into and out of the match network 116. In some examples, variable vacuum capacitors may be used in connection with discrete switching of reactive elements, or variable vacuum capacitors may be used instead of discrete switching of capacitors.

In operation, the processing chamber 104 may present a range of impedances in which the processing chamber 104 may vary during operation. In some examples, energy delivery may be improved while reducing power amplifier dissipation. The match network 116 may be designed to center to an impedance presented by the processing chamber 104 within this range, and then frequency tuning may be used during processing to adapt to the varying load presented by the processing chamber 104. For example, the exciter 340 may be controlled to initially set a frequency of radio frequency signals 342 to an initial frequency (for example and without limitation 13.56 MHz), and then the exciter 340 may be controlled to adjust the frequency up or down in response to the feedback 344 from metrology. As one of ordinary skill in the art will appreciate in view of this disclosure, changing the frequency of the radio frequency signals 342 changes the impedance of the match network 116, so frequency may be used with settings of the match network 116 to achieve a desired source impedance for each generator 102,

In addition, the match network 116 may be designed to operate in various modes in connection with frequency tuning. For example, the match network 116 may be designed to set imaginary impedance only (e.g., without a real impedance component); the match network 116 may be designed to set the real and imaginary impedance or the match network 116 may be designed with switchable real impedance and/or switchable real and imaginary impedance; and the match network 116 may be designed with tunable real and/or imaginary impedance.

It is contemplated that, to account for the imaginary impedance, (+/- J), the controller 112 may be configured to adjust the frequency of the radio frequency signals 342 to tune to an output resonance of the load of the processing chamber 104. In some examples, frequency tuning may be adjusted to achieve zero reflected power to best match an input impedance of a match network. For implementations where the generator 102 is directly coupled to the processing chamber 104, the power amplifier(s), PA_{N}, may be forced into a non-resonant mode at the power amplifiers, PA_{N}, so that power delivery is more closely optimized to the load of the processing chamber 104.

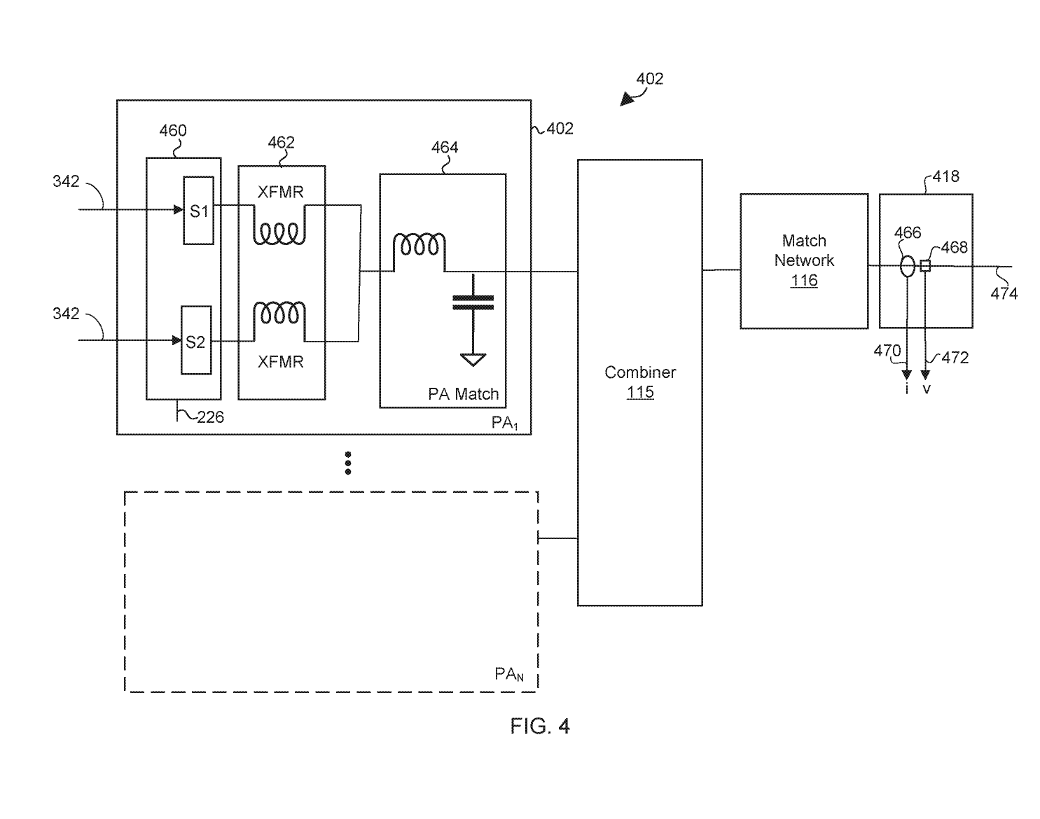

Referring to FIG. 4, shown is an example of a generator 402 that may be used to realize aspects of the generators 102 disclosed herein. As shown, a power amplifier, PA, may comprise a switch section 460, a transformer module 462, and a PA match 464. The power amplifier, PA, may be coupled to the combiner 115, which is further coupled to the match network 116. In this example, the switch section 460 may include one or more switches (e.g., field effect transistors (FETs)), such as switches S1 and S2, that may operate in switch mode in connection with the DC rail voltage 226 to amplify the radio frequency signal 342 responsive to control signals from controller 112 (FIG. 3) to regulate current 470 and/or voltage 472 of output 474 based upon voltage measurements indicative of voltage 472 (e.g., from a voltage sensor 468 of metrology 418) and/or current measurements 470 indicative of current (e.g., with a current transducer 466 (also referred to as a current sensor) of metrology 418). As one of ordinary skill in the art will appreciate in view of this disclosure, the switch section 460 may operate as a class D and/or a class E amplifier. As one of ordinary skill in the art will appreciate, metrology 418 may be designed in various ways just as metrology 118 (FIG. 1) may be designed in various ways.

It should be recognized that two switches, S1 and S2, in the switch section 460 are shown only as an example and that one of ordinary skill in the art will appreciate that one switch or more than two switches may be implemented in variety of topologies. For example and without limitation, full bridge (e.g., an H-bridge) and/or half-bridge topologies may be utilized in the switch section 460.

In some variations of the generator 402, the transformer module 462, the PA match 464, the combiner 115, and the match network 116 may be designed and/or or configured as swappable modules (e.g., a module may be removed and replaced with a similar module configured for different operation) so the generator 402 may be easily configured to match with different processing chambers 104. An overall design goal may be to match a natural impedance of the switch section 460 (which may comprise laterally-diffused metal-oxide semiconductor (LDMOS) field effect transistors) to a load impedance of the processing chamber 104 without a transition to the typical 50 ohm standard impedance (e.g., without an intervening fifty ohm cable or other fifty ohm circuit or component between the generator 402 and processing chamber 104). The typical output impedance of the switch section 460 may be 1 to 2 ohms (and up to 12 ohms in some embodiments), which may be very close to the .5 to 4 ohms of real impedance of a typical processing chamber 104. A switch section 460 exhibiting this range of output impedance allows a reduction in filtering and transformation components. In some variations, the match network 116 may be optimized to center to the impedance presented by the processing chamber 104.

The transformer module 462 may be designed (and/or selected from predesigned modules) to meet an impedance transformation which allows matching to a center of a resistance (“R”) range for the processing chamber 104 without a phase shift. It is also contemplated that the transformer module 462 may be modified to add an additional transformer to achieve an R match without utilizing other match components. As an example without limitation, the modules for the transformer module 462 may be designed as five ohm, ten ohm, twenty five ohm, and fifty ohm modules. It should also be recognized that the transformer module 462 depicted in FIG. 4 may be realized simply by the inherent inductance that couples the switches, S1, S2, to the PA match 464. It should also be recognized that the PA match 464 need not be implemented with an “L” topology, and that any topology may be utilized.

The power amplifier, PA, may be designed to allow delivered power to be achieved over a wide range of R impedance. For example, the power amplifier, PA, may be designed for a wider R range by setting an average delivered power to be less than a peak power of the power amplifier system. More specifically, without limitation, the peak power of a power amplifier may be designed to be six kW while the average delivered power is limited to three kW to allow three kW to be delivered across a wider R range. The higher peak power may be achieved by adding additional power amplifiers, PA_{N}, (to increase the value of N).

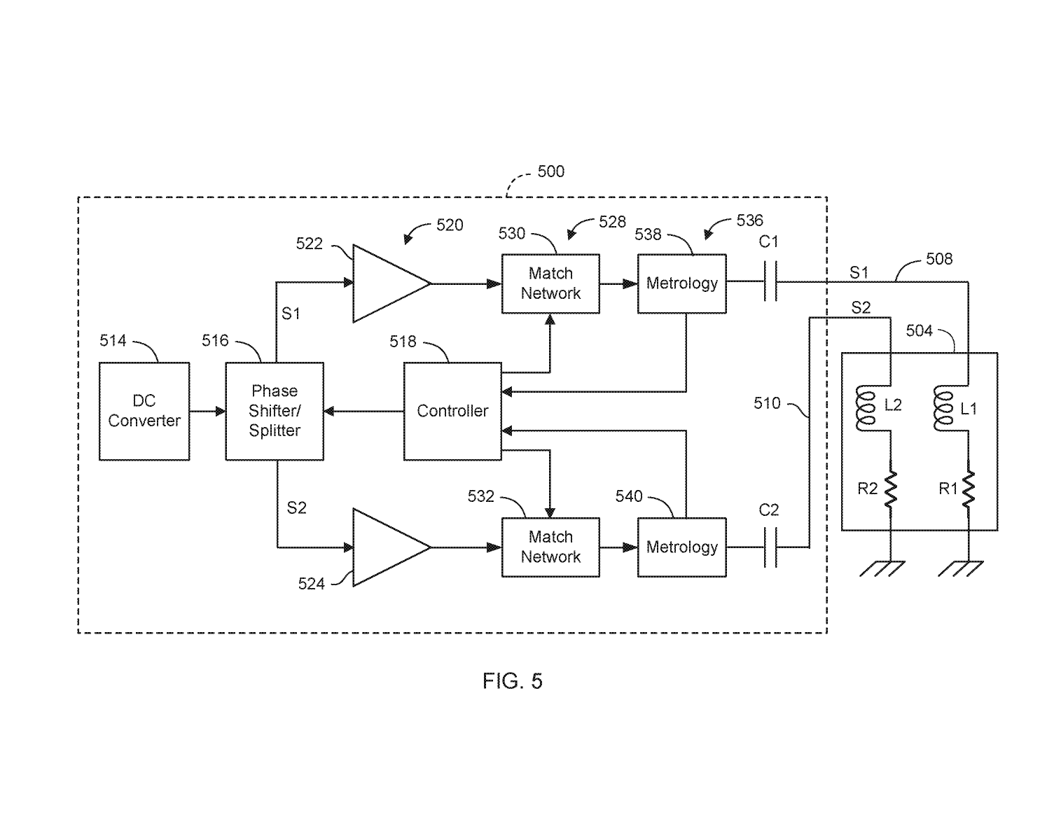

Additional reference is made to FIG. 5, which illustrates a block diagram of a single generator 500 configured to provide power to a processing chamber 504. The processing chamber 504 may be identical or substantially similar to the processing chamber 104 (FIG. 1). In the embodiment of FIG. 5, the generator 500 is configured to provide a first signal comprising a frequency to the processing chamber 504 and a second signal comprising the frequency and phase shifted relative to the first signal to the processing chamber 504. In some embodiments, the phase shift is adjustable. In other embodiments, the phase shift is maintained at 90°, such as by circuitry as described herein. Portions of the generator 500 may be similar or substantially similar to portions of the generators described with reference to FIGS. 1-4.

The processing chamber 504 may include or be modeled has having a first coil L1 coupled in series with a first resistor R1. The series combination of the first coil L1 and the first resistor R1 may be coupled to a ground, which may be a chassis ground of the processing chamber 504. During operation of the processing chamber 504, the first signal S1 is coupled to the series combination of the first coil L1 and the first resistor R1 by way of a first line 508. The processing chamber 504 may also include or be modeled has having a second coil L2 coupled in series with a second resistor R2. The first resistor R1 may be or may include resistance of the first coil L1 and the second resistor R2 may be or may include resistance of the second coil L2. The series combination of the second coil L2 and the second resistor R2 may be coupled to a ground, which may be a chassis ground of the processing chamber 504. The series combination of the first coil L1 and the first resistor R1 may be coupled to the same ground as the series combination of the second coil L2 and the second resistor R2. During operation of the processing chamber 504, the second signal S2 is coupled to the series combination of the second coil L2 and the second resistor R2 by way of a second line 510. Thus, the generator 500 alone is configured to generate two signals that are configured to provide power to the first coil L1 and the second coil L2 in the processing chamber 504.

The first line 508 may include a first series capacitor C1 or have an intrinsic capacitance C1 and the second line 510 may include a second series capacitor C2 or have an intrinsic capacitor C2. The series combination of the first capacitor C1, the first coil L1, and the first resistor R1 may form a first resonant circuit or first tank circuit. Likewise, the series combination of the second capacitor C2, the second coil L2, and the second resistor R2 may form a second resonant circuit or second tank circuit.

In the embodiment of FIG. 5, the generator 500 may include a DC converter 514 that receives power, such as via a DC source (not shown in FIG. 5) and outputs a signal having the above-described frequency. The frequency may be tuned to the resonance of the first tank circuit and/or the second tank circuit. For example, the frequency may be a variable RF frequency (as discussed herein) and the first tank circuit and the second tank circuit may be RF resonant tank circuits. In some embodiments, the DC converter 514 may be identical or similar to the exciter 340 described in reference to FIG. 3. The signal generated by the DC converter 514 may be received by a phase shifter/splitter 516 that splits the signal into a the first signal S1 and the second signal S2. The phase shifter/splitter 516 may also shift the phase of the second signal S2 relative to the first signal S1. In some embodiments, the second signal S2 is phase shifted 90° relative to the first signal S1. In other embodiments, the phase angle may be other amounts. The phase angle may be set by a controller 518 as described herein. The controller 518 may also set the frequency output by the DC converter 514.

The generator 500 may include a plurality of power amplifiers 520 that amplify the first signal S1 and the second signal S2. In the embodiment of FIG. 5, the generator 500 includes a first power amplifier 522 that amplifies the first signal S1 and a second power amplifier 524 that amplifies the second signal S2. The output of the first power amplifier 522 may be referred to as a first amplified signal and the output of the second power amplifier 524 may be referred to as a second amplified signal. The power amplifiers 520 may be push-pull type amplifiers. In some embodiments, the power amplifiers 520 are class E amplifiers (e.g., push-pull class E amplifiers). In some embodiments, the power output by each of the power amplifiers 520 may be between 4kW and 6kW, but other power levels outside of this range are certainly contemplated. The power amplifiers 520 may operate at approximately 13MHz, but may provide different power outputs at different frequencies.

The generator 500 may include a plurality of matched networks 528 that are coupled to the outputs of the power amplifiers 520. In the embodiment of FIG. 5, the generator 500 includes a first matched network 530 coupled to the output of the first power amplifier 522 and a second matched network 532 coupled to the output of the second power amplifier 524. The matched networks 528 match the impedances of the outputs of the power amplifiers 520 with the impedances of the first and second tank circuits. Thus, the first matched network 530 matches the impedance of the output of the first power amplifier 522 with the impedance of the first tank circuit and the second matched network 532 matches the output of the second power amplifier 524 with the impedance of the second tank circuit. In other embodiments, the plurality of matched networks 528 may match the output impedances of the power amplifiers 520 with the coils L1 and L2 within the processing chamber 504.

The circuitry in the match networks 528 may be fixed in some embodiments. For example, if the impedances of the outputs of the power amplifiers 520 are fixed and the impedances of the tank circuits are fixed, the matching circuitry within the match networks 528 may be fixed. In other embodiments, the impedances of the outputs of the power amplifiers 520 and/or the impedances of the tank circuits may vary or may be fixed, but may not be readily known. In such situations, the match networks 530 may vary impedances in response to one or more input signals or instructions from the controller 518. Impedances in the match networks 530 may be varied by variable capacitance, variable reactance, and/or variable inductors, which are nonlimiting examples. The impedances in the match networks 530 may be fixed and/or may be adjustable (e.g., by manual adjustment).

The generator 500 may include one or more metrology devices 536 configured to measure voltage and/or current of the first signal S1 and/or the second signal S2 being delivered to the processing chamber 504. In the embodiment of FIG. 5, the generator 500 includes a first metrology device 538 configured to measure voltage and/or current of the first signal S1. The generator 500 also includes a second metrology device 540 configured to measure voltage and/or current of the second signal S2. In the embodiment of FIG. 5, data generated by the metrology devices 536 may be indicative of voltage, current, and/or power and are input to the controller 518. The controller 518 may analyze the data and, based on the analysis, determine power transferred to the processing chamber 504 via the first signal S1 and the second signal S2. The controller 518 may also determine and adjust the phase angle between the first signal S1 and the second signal S2. Based on all the analysis, the controller 518 may change power in the first signal S1 and/or the second signal S2 by controlling gain of one or more of the power amplifiers 520. The controller 518 may operate similarly to the controller of FIG. 2 to control a voltage provided to each of the power amplifiers 520 (in order to control the gain). In addition, the controller 518 may be configured (e.g., specifically configured by software and/or hardware) to control the power amplifiers 520 to produce multi-level pulsing established by an operator of the generator 500. The controller 518 may also adjust the impedance via the plurality of matched networks 528 to improve power transfer from the power amplifiers 520 to the processing chamber 504. In the context of multi-level pulsing, the match networks may dynamically be set, as previously discussed herein, responsive to different pulses or may be fixed to match a specific pulse level while being imperfectly matched to one or more other levels.

In addition to the foregoing, the controller 518 may adjust the phase angle between the first signal S1 and the second signal S2, such as by sending instructions to the phase shifter/splitter 516. In some embodiments, the controller 518 adjusts the phase angle between the first signal S1 and the second signal S2 to maintain a 90° phase angle between the first signal S1 and the second signal S2.

During operation of the generator 500, the controller 518 may transmit signals or instructions to the DC converter 514, which cause the DC converter 514 to generate a waveform, such as a sinusoidal waveform, having a predetermined frequency, such as about 13MHz. The phase shifter/splitter 516 may generate the first signal S1 and the second signal S2, which may be 90° phase shifted relative to the first signal S1. In some embodiments, the DC converter 514 or similar device may generate the first signal S1 and the second signal S2 without use of the phase shifter/splitter 516.

The first signal S1 is amplified by the first power amplifier 522 and the second signal S2 is amplified by the second power amplifier 524. In some embodiments, the controller 518 may control the amplification of the power amplifiers 520 individually, which, at least partially, sets the power output to the first coil L1 and the second coil L2 individually. The impedances of the matched networks 528 may be set individually by the controller 518 so the impedance of the output of the first power amplifier 522 is matched to the first tank circuit and the impedance of the output of the second power amplifier 524 is matched to the second tank circuit. The capacitors C1 and C2 block DC power from being provided to the processing chamber 504.

The metrology devices 536 may measure voltage and/or current output from the generator 500 to the first coil L1 and the second coil L2 individually. Data indicative of voltage and/or current may be transmitted to the controller 518. The controller 518 may measure power to each of the coils L1 and L2 to determine if a predetermined power is being delivered to the coils L1 and L2. If the predetermined power is not being delivered, the controller 518 may adjust the impedances in the match networks 528 and/or the power output by the power amplifiers 520. The controller 518 may also be configured to provide output regulation based upon voltage and/or current responsive to feedback from the metrology devices 536. The controller 518 may also determine the phase angle between the first signal S1 and the second signal S2 based at least in part on the data transmitted from the metrology devices 536. If the phase angle is not at a predetermined angle or within predetermined angle limitations, the controller 518 may generate instructions that cause the phase shifter/splitter 516 to correct the phase angle. Per the foregoing, the coils L1 and L2 in the processing chamber 504 are powered with a single generator that generates two RF sources that are phase shifted by a predetermined phase angle, such as 90°.

In some embodiments, the impedances of the first tank circuit may and the second tank circuit may be substantially equal, but not tuned to the frequency of the first signal S1 and the second signal S2. In these situations, the controller 518 and/or an operator may change the frequency of the signals S1 and S2 to match the impedances of the first tank circuit and the second tank circuit. In other embodiments, the impedances of the first coil L1 and the second coil L2 may not match or may have a difference greater than a predetermined difference allowed for operation of the processing chamber 504. The imbalance between the coils L1 and L2 may be overcome by tuning either of the coils L1 and/or L2. Tuning may be performed automatically, such as via instructions or signals generated by the controller 518, or manually, such as by a user.

In some embodiments, the first coil L1 and the second coil L2 operate at different currents. Thus, there may be a current ratio between the first coil L1 and the second coil L2. Current balance may be achieved by controlling the output power of the power amplifiers 520 or via other techniques. When the correct or predetermined current ratio has been achieved, power to the processing chamber 504 may be regulated by adjusting output power of the power amplifiers 520 and/or the DC converter 514. The user may then have two variables to control, delivered power to the processing chamber 504 and current ratio between the first coil L1 and the second coil L2.

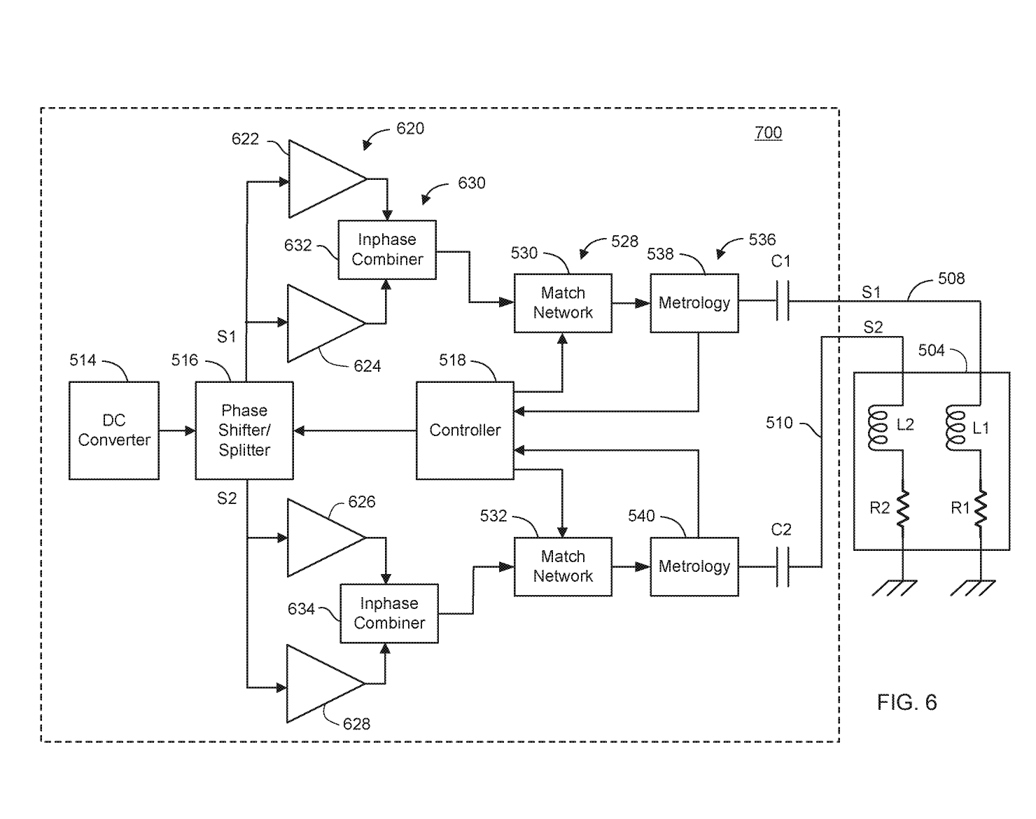

Additional reference is made to FIG. 6, which is a block diagram of a generator 600, which is an embodiment of the generator 500 but has more than two power amplifiers. The output of the generator 600 may be the same or similar to the generator 500. In the embodiment of FIG. 6, the generator 600 includes four power amplifiers 620, which are referred to individually as a first power amplifier 622, a second power amplifier 624, a third power amplifier 626, and a fourth power amplifier 628. In other embodiments, the generator 600 may include three or more than four power amplifiers. The first power amplifier 622 and the second power amplifier 624 are configured to amplify the first signal S1 and the third power amplifier 626 and the fourth power amplifier 628 are configured to amplify the second signal S2.

Outputs of the four power amplifiers 620 may be input to one or more combiners 630 that may be inphase combiners. The combiners 630 are configured to combine signals from a plurality of power amplifiers. The combiners 630 enable the generator 600 to generate high power using a plurality of low power amplifiers. In the embodiment of FIG. 6, outputs of the first power amplifier 622 and the second power amplifier 624 may be input to a first combiner 632 and the outputs of the third power amplifier 626 and the fourth power amplifier 628 may be input to a second combiner 634. Further processing of the first signal S1 and the second signal S2 may be similar or identical to the processing of the first signal S1 and the second signal S2 from the power amplifiers 520 described in FIG. 5.

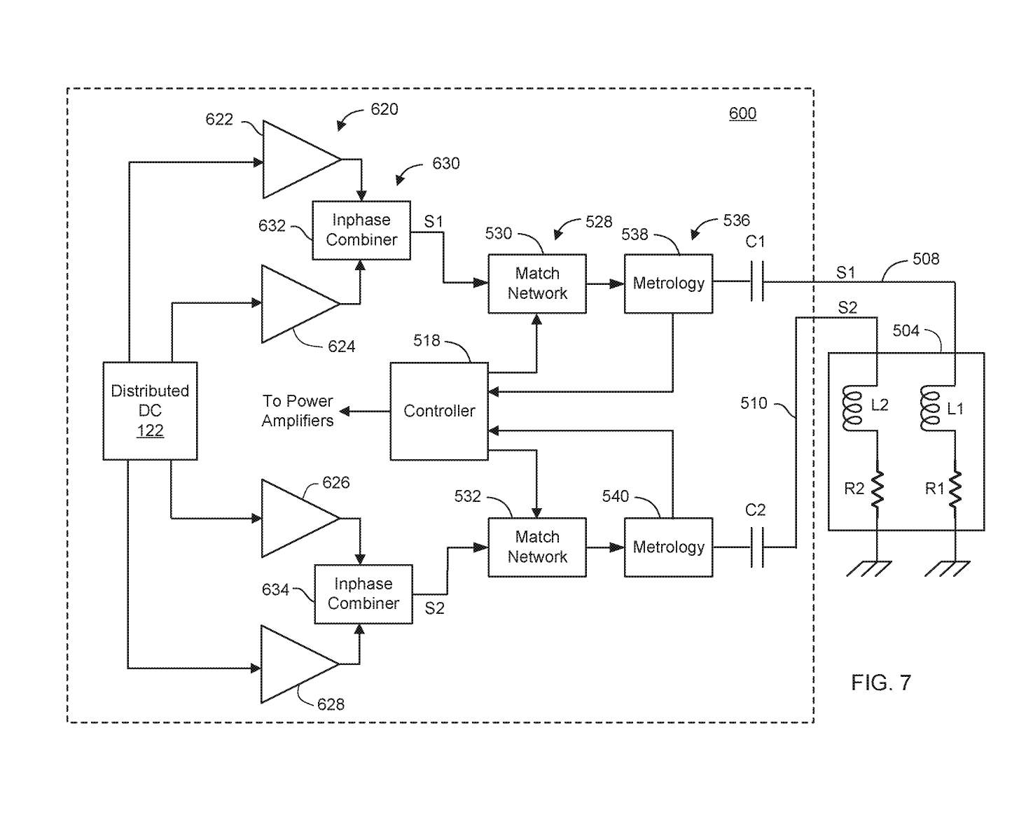

Additional reference is made to FIG. 7, which illustrates a generator 700, which is an embodiment of the generator 600 (FIG. 6) wherein distributed DC 122 is input to each of the four power amplifiers 620. In the embodiment of FIG. 7, each of the four power amplifiers 620 may generate the first and second signals S1 and S2. Instructions or signals generated by the controller 518 may be transmitted to each of the four power amplifiers 620 rather than the phase shifter/splitter 516 (FIG. 6). Thus, each of the four power amplifiers 620 may individually adjust amplitude, frequency, and phase of the first and second signals S1 and S2. In all other operation, the generator 600 of FIG. 7 may operate in the same manner as the generator 600 of FIG. 6.

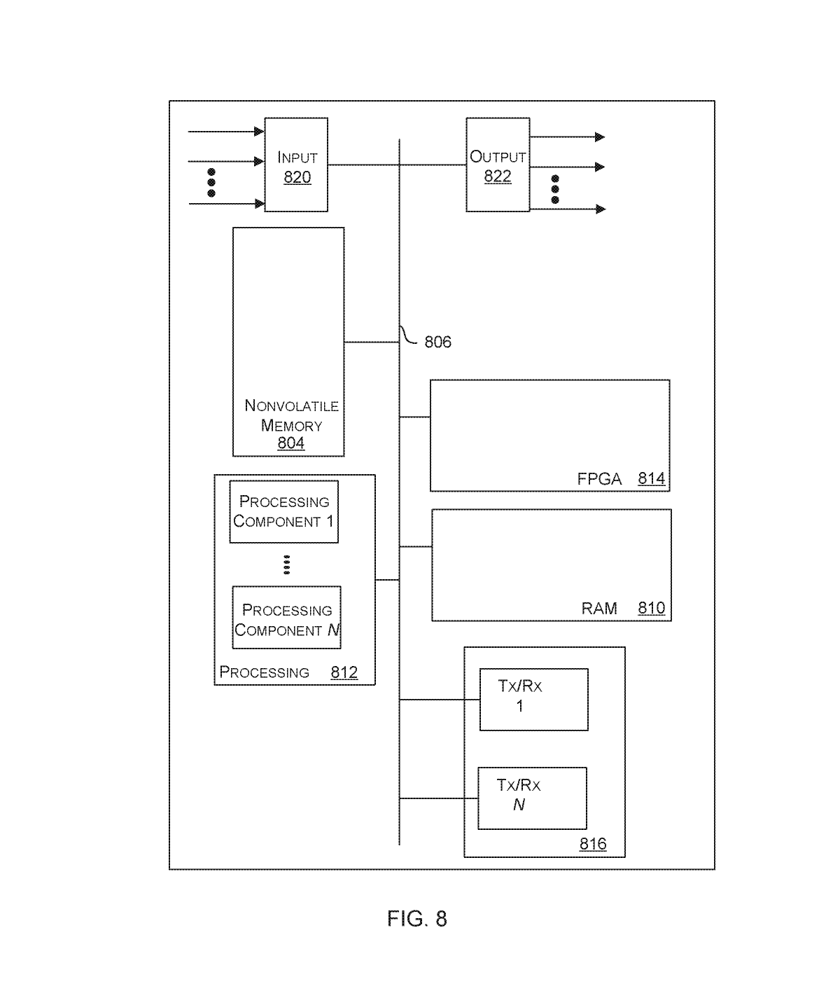

The methods described in connection with the embodiments disclosed herein may be embodied directly in hardware, in processor-executable code encoded in a non-transitory tangible processor readable storage medium, or in a combination of the two. In general, hardware, software, firmware, digital logic components, and field programmable gate arrays among other constructs function to provide logic to execute logical operations to effectuate the functions and methods described herein, and as a consequence, the term logic should be broadly construed unless otherwise limited. Referring to FIG. 8 for example, shown is a block diagram depicting physical components that may be utilized to realize the controllers 112 (FIG. 1) and 518 (FIG. 5) according to various embodiments. As shown in FIG. 8, nonvolatile memory 804 is coupled to a bus 806 that is also coupled to random access memory ("RAM") 810, a processing portion (which includes N processing components) 812, a field programmable gate array (FPGA) 814, and a transceiver component 816 that includes N transceivers. None of these components are required, and any combination of these may be included. For instance, where an FPGA 814 is implemented, the processing portion 812 may not be used, and vice versa. Although the components depicted in FIG. 5 represent physical components, FIG. 8 is not intended to be a detailed hardware diagram; thus, many of the components depicted in FIG. 8 may be realized by common constructs or distributed among additional physical components. Moreover, it is contemplated that other existing and yet-to-be developed physical components and architectures may be utilized to implement the functional components described with reference to FIG. 8.

In general, the nonvolatile memory 804 is non-transitory memory that functions to store (e.g., persistently store) data and processor-executable code (including executable code that is associated with effectuating the methods described herein). In some embodiments for example, the nonvolatile memory 804 includes bootloader code, operating system code, file system code, and non-transitory processor-executable code to facilitate the execution of a method of, for example, frequency tuning and/or control of match network 116, as described herein.

In many implementations, the nonvolatile memory 804 is realized by flash memory (e.g., NAND or ONENAND memory), but it is contemplated that other memory types may be utilized as well (e.g., read-only memory (ROM), NV-RAM, magnetic storage). Although it may be possible to execute the code from the nonvolatile memory 804, the executable code in the nonvolatile memory is typically loaded into RAM 810 and executed by one or more of the N processing components in the processing portion 812.

The N processing components in connection with RAM 810 generally operate to execute the instructions stored in nonvolatile memory 804 to enable methods disclosed herein that are carried out by controllers 112 and 518. For example, non-transitory, processor-executable code to effectuate the methods described herein may be persistently stored in nonvolatile memory 804 and executed by the N processing components in connection with RAM 810. As one of ordinarily skill in the art will appreciate, the processing portion 812 may include a video processor, digital signal processor (DSP), micro-controller, graphics processing unit (GPU), or other hardware processing components or combinations of hardware and software processing components (e.g., an FPGA or an FPGA including digital logic processing portions).

In addition, or in the alternative, the processing portion 812 may be configured to effectuate one or more aspects of the methodologies described herein. For example, non-transitory processor-readable instructions may be stored in the nonvolatile memory 804 or in RAM 810 and when executed on the processing portion 812, cause the processing portion 812 to perform a method of controlling the frequency of radio frequency signals 342, S1, S2, DC rail voltage 226, and/or a position of match networks 116 and 528.

In addition, the FPGA 814 may include non-transitory processor-executable code to program the FPGA to facilitate functions disclosed herein. For example, the FPGA 814 may be utilized by metrology 118, 418, and 536 to sample and digitize measured power-related parameters (e.g., current, voltage, power, phase, frequency and reflected power). The FPGA 814 may include on-board memory to access data such as the target multi-level waveform, or may access off-chip memory such as the nonvolatile memory 804 accessible via bus 806.

An input component 820 operates to receive signals (e.g., feedback 344 from metrology 118, 418, 536 and/or signals from the user interface 108 such as a target multi-level pulsed waveform) that are indicative of one or more aspects of the target waveform or conditions of the nonlinear plasma load of processing chambers 104 and 504. The signals received at the input component may include, for example, a measurement of voltage, current, and/or power delivered to the plasma processing chambers 104 and 504. An output component 822 generally operates to provide one or more analog or digital signals to effectuate an operational aspect of the controllers 112 and 518 generally. For example, the output portion 822 may provide the controller signals to driver exciter 340 (as described with reference to FIG. 3) and the DC control 114 as described with reference to FIG. 2.

The depicted transceiver component 816 includes N transceiver chains, which may be used for communicating with external devices via wireless or wireline networks. Each of the N transceiver chains may represent a transceiver associated with a particular communication scheme (e.g., WiFi, Ethernet, Profibus, etc.).

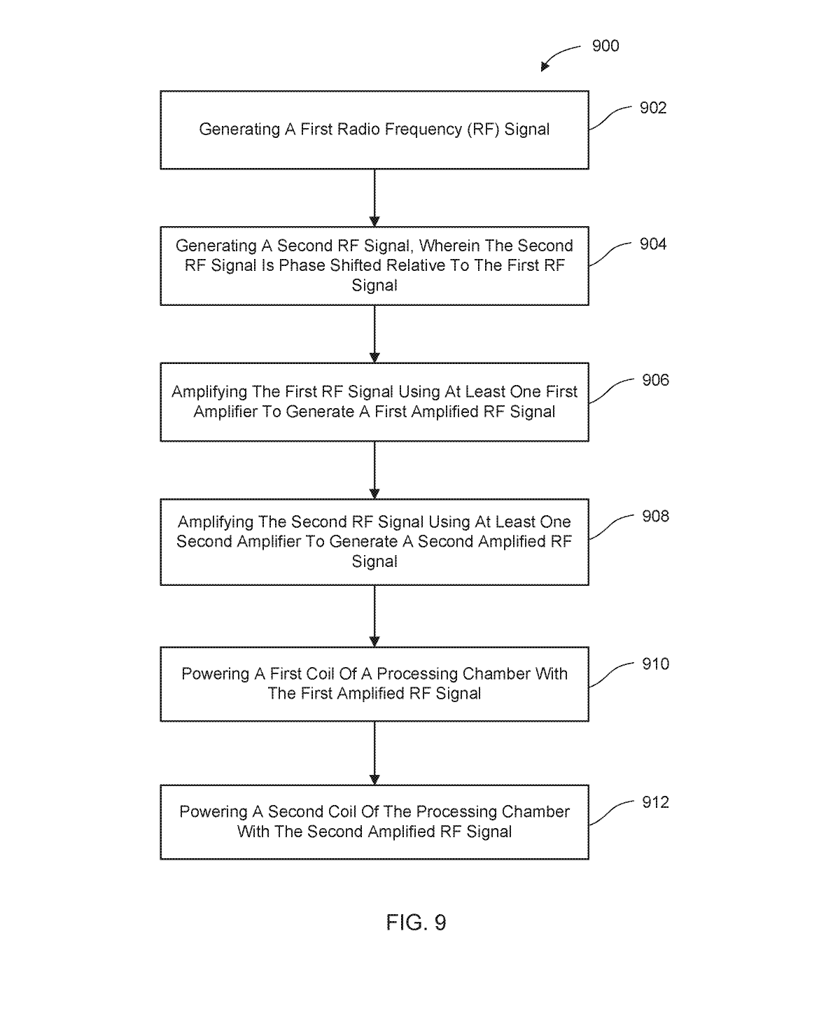

Additional reference is made to FIG. 9, which is a flowchart illustrating a method 900. The method 900 includes, in block 902, generating a first radio frequency (RF) signal (e.g., first signal S1). The method 900 includes, in block 904, generating a second RF signal (e.g., second signal S2), wherein the second RF signal is phase shifted relative to the first RF signal. The method 900 includes, in block 906, amplifying the first RF signal using at least one first amplifier (e.g., first amplifier 522) to generate a first amplified RF signal. The method 900 includes, in block 908, amplifying the second RF signal using at least one second amplifier (e.g., second amplifier 524) to generate a second amplified RF signal. The method 900 includes, in block 910, powering a first coil (e.g., first coil L1) of a processing chamber (e.g., processing chamber 504) with the first amplified RF signal. The method 900 includes, in block 912, powering a second coil (e.g., second coil L2) of the processing chamber with the second amplified RF signal.

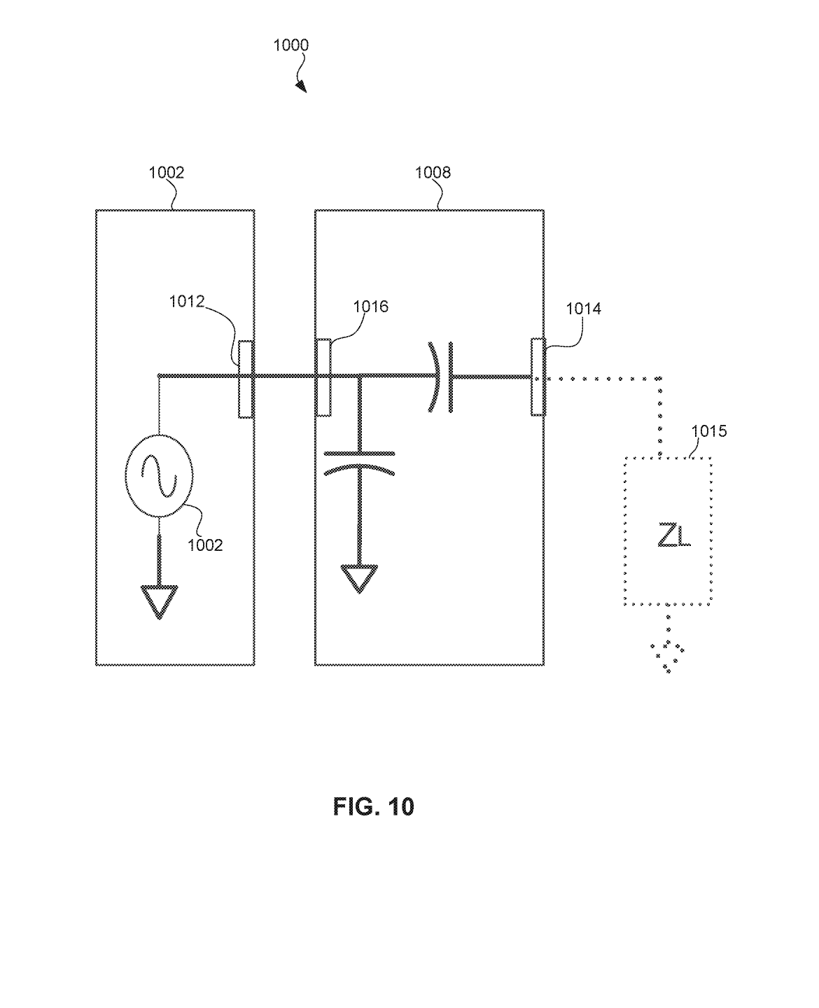

Referring to FIG. 10, shown is an example of a power delivery system 1000 comprising a generator 1001 and a match network 1008. Aspects of the power delivery system 1000 may be incorporated into any of the embodiments described herein. The system 1000 may provide power to a load 1015 (for example the processing chamber 104). The load 1015 and its connection to the match network 1008 are depicted with dotted lines because the load 1015 is optional and may not be a part of the power delivery system 1000. The generator 1001 may comprise a first sensor 1012 that may be used to control power delivery. The first sensor 1012 may comprise a directional coupler and/or a VI sensor. The match network 1008 may comprise a second sensor 1014 that may operate as a plasma interface monitor that may be used to monitor load characteristics, line power, voltage, and current delivered to the load 1015. The second sensor 1014 may comprise a directional coupler and/or a VI sensor. Although directional couplers and VI sensors are used as examples herein, it should be recognized that other types of sensors may be used. The generator 1001 may also comprise a signal source 1002.

The signal source 1002 may comprise any of a wide variety of circuits, components, and/or systems capable of generating an RF signal sufficient for forming and maintaining plasma. The signal source 1002 may comprise one or more signal generators, oscillators, filters, amplifiers, and/or other circuits, components, and systems associated with the generation of RF signals. The signal source 106 may be capable of providing RF signals at a variety of power levels and frequencies. In one example, the signal source 1002 may provide an RF signal at a frequency of 13.56 megahertz (MHz). In other examples, the signal source may provide an RF signal at another frequency (e.g., higher or lower than 13.56 MHz) such as 40MHz or 60MHz. The signal source 1002 may comprise a source impedance of 50 ohms, but this is merely an example and the source impedance of the signal source 1002 may be different than 50 ohms.

The match network 1008 may also comprise a third sensor 1016 that may operate to provide match i/p control measurement (e.g., of current and power) that may be used to enhance (e.g., maximize) power transfer from the generator 1002 to the load 1015. The third sensor 1016 may each comprise a directional coupler and/or a VI sensor. The load 1015 may comprise the plasma chamber 104, and the second sensor 1014 may operate as a plasma interface monitor that may be used to monitor plasma characteristics, line power, voltage, and current delivered to the plasma chamber 104. The generator 1002 and the match network 1008 may be calibrated using short-open-load (SOL) standard calibration methodology.

When the load 1015 comprises a dynamic plasma load, RF measurements of the dynamic plasma load can be very challenging given the reactive nature of the plasma which is generally at a very high phase--on the order of close to 90°. The generator 1002 may operate with the first sensor 1012 being realized by a 50 ohm directional coupler to provide measurements, and the match network 1008 may operate with a variable or a fixed matching network with a VI sensor at a plasma interface. The generator 1002 may have very good accuracy when the measurements are made at 50 ohms but the match output measurement may not be as accurate/repeatable as desired.

Measurement at 50 ohms may not be an accurate representation of plasma behavior because of unknown match characteristics such as efficiency of the match network 1008 or variability in matching networks. Semiconductor wafer process demands much tighter precision at plasm chamber interface for a better wafer processing repeatability.

Referring to FIG. 11, shown is an example of a generator 1100 that may comprise a signal source 1002 coupled to a transformer 1104 at a first node 1111. Coupled between the transformer 1104 and a second node 1113 are a first sensor 1106, an inductor 1108, a capacitor 1110, and a second sensor 1112 As shown, the generator 1100 may be coupled to the load 1015. As discussed above, the signal source 1002 may be a signal source capable of providing RF power. Accordingly, signal source 106 may be an RF signal source, and generator 1100 may be an RF generator and may alternatively be referred to herein as RF generator 1100. The signal source 1002 may be capable of providing frequency tuning to facilitate matching the signal source 1002 with the load 1015.

Collectively, the transformer 1104, the inductor 1108, and the capacitor 1110 may function as an impedance transformation portion of the generator 1100. The impedance transformation portion may function to convert an impedance of the signal source 1002 into an impedance that may be, for example and without limitation, one ohm, two ohms, or three ohms to match the load 1015 depending upon a process that is being carried out (where the process affects an impedance of load 1015).

The transformer 1104 may function to adjust a resistive part of the impedance to a resistance that is relatively close to an operating range of the load 1015. In the context of a Smith chart, the transformer 1104 may move the resistance presented to the load 1015 along the horizontal axis of the Smith chart (e.g., to the left portion of the horizontal axis). As shown, the first sensor 1106 may be positioned at a high side (in contrast to a ground side) of the secondary winding 1118 of the transformer 1104 so that the first sensor 1106 is positioned to be presented with a resistive portion of impedance that is relatively close to an operating range of the load 1015.

The transformer 1104 may comprise a primary winding 1116 and the secondary winding 1118. The transformer 1104 may be an N:1 transformer where N:1 is the ratio of the number turns in the primary winding 1116 to the number of turns in the secondary winding 1118, and N may define a resistance that the source impedance of the signal source 1002 is transformed to. In general, N may be equal to the square root of (Rin/Rout) where Rin is a resistance at the signal source 1002 side of the primary winding 1116 and Rout is a resistance at the opposite side of the transformer 1004 (e.g., at the location of the first sensor 1106). For example, if the resistance is 50 ohms at the primary side of the transformer 1104 and it is desired to have a two-ohm impedance at the secondary side of the transformer (e.g., where the first sensor 1106 is positioned), then the transformer 1104 may be realized by a 5:1 transformer. As another example, if the resistance is 50 ohms at the primary side of the transformer 1104 and the desired resistance at the secondary side of the transformer 1104 is approximately 1 ohm, then the transformer 1104 may be realized by a 7:1 transformer. The transformer may be an air or ferrite based transformer.

The first sensor 1106 may comprise a directional coupler and/or a VI sensor, or another variety of sensor. The first sensor 1106 may provide an intermediate network measurement. The first sensor 1106 may provide a measurement that is used for protection of the generator 1100 and power components. For example, the first sensor 1106 may provide measurements to protect the signal source 1002. Although not shown in FIG. 11, an additional sensor may be placed between the primary winding 1116 of the transformer 1104 and the signal source 1002. The additional sensor may be used in part to regulate power-related aspects (e.g., power, current, and/or voltage) of the signal source 1002. The additional sensor may comprise a directional coupler, a VI sensor, and/or another type of sensor.

As shown, the inductor 1108 may be a series inductor. The inductor 1108 may be fixed. The inductor 1108 may comprise more than one inductor arranged in series. The inductor 1108 may comprise more than one inductor arranged in parallel. The inductor may function to move an impedance along a clockwise direction of a constant-resistance circle of a Smith chart.

The capacitor 1110 may be a fixed capacitor. The capacitor 1110 may be an adjustable capacitor. The capacitor 1110 may be a combination of a fixed capacitor and an adjustable capacitor. Any fixed capacitor may be realized by more than one capacitor arranged in series or in parallel. A variable capacitor may be realized by a vacuum variable capacitor. A variable capacitor may be realized by a digitally addressable array of fixed capacitors that may be switched in and out of use using switches (e.g., PIN diode switching). A value of the capacitor 1110 may be fixed in advance of any processing taking place in a plasma chamber. Even if fixed in advance of processing, the capacitor 1110 may be an adjustable capacitor. It is also contemplated that the capacitor 1110 may be adjusted during processing in a plasma chamber if the capacitor 1110 comprises an adjustable capacitor. As discussed above, the frequency of the signal source 1002 may be adjusted (increased and/or decreased) to provide further impedance adjustment of the impedance transformation portion. The impedance transformation portion may be set to adjust reactance so that the first sensor 1106 “sees” 0 deg phase.

The second sensor 1112 may provide a low phase measurement at an output of the generator 1100. The second sensor 1112 may comprise a directional coupler, a VI sensor, and/or another type of sensor. Measurements from the first sensor 1106 and the second sensor 1112 may be used to calculate and to control more accurate power, voltage, and/or current delivered to plasma load. One or more of the transformer 1104, inductor 1108, and capacitor 1110 may be characterized and the characterization may be used in connection with the measurements from the first sensor 1106 and the second sensor 1112 to more accurately calculate and to more accurately control power, voltage, and/or current delivered to the load 1015. The impedance transformation portion (e.g., comprising the transformer 1104, inductor 1108, and the capacitor 1110) may be characterized in terms of impedance as a function of frequency and the resultant impedance of the impedance transformation portion. Characterization may enable losses of the impedance transformation portion to be accounted for when calculating power, voltage, and/or current delivered to the load 1015 (e.g., plasma load).

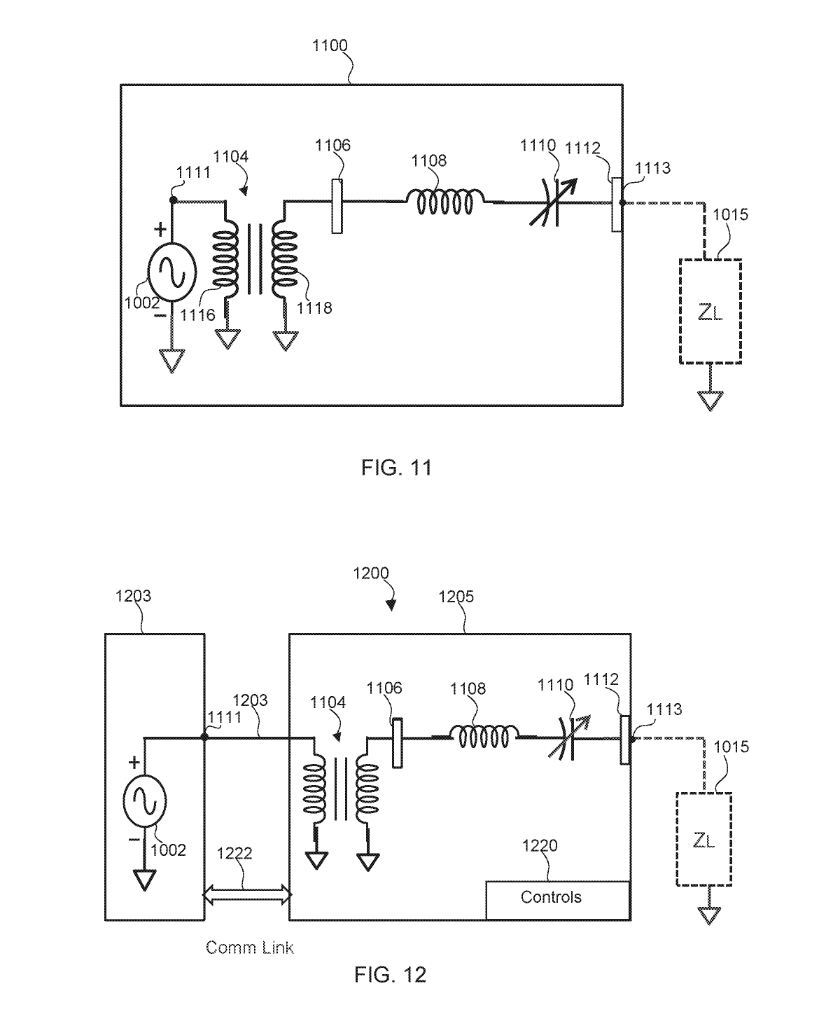

Referring to FIG. 12, shown is a power delivery system 1200 comprising a generator 1203 and an impedance transformation portion 1205. The power delivery system 1200 may operate in much the same way as the generator 1100. The generator 1203 and the impedance transformation portion 1205 may be coupled by a power transmission line 1203 (e.g., a coaxial cable) and by a data communication link 1222. The impedance transformation portion 1205 may comprise controls 1220 to enable control of the impedance transformation portion 1205. The controls 1220 may receive information from the second sensor 1112 that is indicative of one or more power-related parameters such as current, voltage, power, impedance, and phase. The information may be analog information that is sampled and converted to digital information that is indicative of the one or more power related parameter values. Controls 1220 may comprise processing components such as those described with reference to FIG. 8.

The digital information (e.g., electrical parameter value information) may be communicated to the generator 1203 via a communication link 1222. The data communication link 1222 may be a digital communication link. The data communication link 1222 may be a bidirectional communication link. The data communication link 1222 may be a bidirectional communication link that operates substantially continuously to enable data communication between the generator 1203 and the impedance transformation portion 1205. The generator 1203 may comprise controls (not shown in FIG. 12) such as those described with reference to FIG. 8. The controls of the generator 1203 and the controls 1220 may comprise control logic. The controls in the generator 1203 may enable the generator 1203 to control aspects of the impedance transformation portion 1205 and the generator 1203. For example, if the capacitor 1110 is adjustable, the generator 1203 may control the capacitor 1110 in advance of operation to fix the capacitor 1110 at a fixed capacitance. It is also contemplated that the generator 1203 may control the capacitor 1110 during operation of the power delivery system 1200. It is also contemplated that one or both of the generator 1203 and the impedance transformation portion 1205 may communicate with a centralized controller via a data communication link 1222.

Some portions of the present disclosure are presented in terms of algorithms or symbolic representations of operations on data bits or binary digital signals stored within a computing system memory, such as a computer memory. These algorithmic descriptions or representations are examples of techniques used by those of ordinary skill in the data processing arts to convey the substance of their work to others skilled in the art. An algorithm is a self-consistent sequence of operations or similar processing leading to a desired result. In this context, operations or processing involves physical manipulation of physical quantities. Typically, although not necessarily, such quantities may take the form of electrical or magnetic signals capable of being stored, transferred, combined, compared or otherwise manipulated. It has proven convenient at times, principally for reasons of common usage, to refer to such signals as bits, data, values, elements, symbols, characters, terms, numbers, numerals or the like. It should be understood, however, that all of these and similar terms are to be associated with appropriate physical quantities and are merely convenient labels. Unless specifically stated otherwise, it is appreciated that throughout this specification discussions utilizing terms such as “processing,” “computing,” “calculating,” “determining,” and “identifying” or the like refer to actions or processes of a computing device, such as one or more computers or a similar electronic computing device or devices, that manipulate or transform data represented as physical electronic or magnetic quantities within memories, registers, or other information storage devices, transmission devices, or display devices of the computing platform.

As will be appreciated by one skilled in the art, aspects of the present disclosure may be embodied as a system, method or computer program product. Accordingly, aspects of the present disclosure may take the form of an entirely hardware embodiment, an entirely software embodiment (including firmware, resident software, micro-code, etc.) or an embodiment combining software and hardware aspects that may all generally be referred to herein as a "circuit," "module" or "system." Furthermore, aspects of the present disclosure may take the form of a computer program product embodied in one or more computer readable medium(s) having computer readable program code embodied thereon.

As used herein, the recitation of "at least one of A, B and C" is intended to mean "either A, B, C or any combination of A, B and C." The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

What is claimed is:

1. A system comprising:
a signal source configured to provide power to a primary side of a transformer;
an inductor and a capacitor arranged between the transformer and a node;
a first sensor coupled to a secondary of the transformer;
a second sensor coupled to the second node; and
logic to receive information from the first sensor and the second sensor and calculate an electrical parameter value.

2. The system of claim 1, wherein the electrical parameter value comprises an electrical parameter value selected from the group consisting of power, voltage, current, phase, and impedance values.

3. The system of claim 1, wherein the inductor and a capacitor are arranged in series.

4. The system of claim 1 comprising a model of the transformer, inductor, and the capacitor, wherein the logic is configured to calculate the electrical parameter value based upon the model.

5. The system of claim 1, wherein the signal source is in a common housing with the transformer, inductor, and the capacitor.

6. The system of claim 1, wherein the signal source is in a separate housing from the transformer, inductor, and the capacitor.

7. The system of claim 1, wherein the logic is configured to use the information from the first sensor to protect components of the system.
